(19) United States
(12) Patent Application Publication
(10) Pub. No.: US 2013/0149815 A1
(43) Pub. Date: Jun. 13, 2013

(54) NONVOLATILE MEMORY ELEMENT MANUFACTURING METHOD AND NONVOLATILE MEMORY ELEMENT

(71) Applicants: Hideaki Murase, Osaka (JP); Takumi Mikawa, Shiga (JP); Yoshio Kawashima, Osaka (JP); Atsushi Himeno, Osaka (JP)

(72) Inventors: Hideaki Murase, Osaka (JP); Takumi Mikawa, Shiga (JP); Yoshio Kawashima, Osaka (JP); Atsushi Himeno, Osaka (JP)

(21) Appl. No.: 13/810,465

(22) PCT Filed: Sep. 10, 2012
(86) PCT No.: PCT/JP2012/005718

§ 371 Date: Jan. 16, 2013

(30) Foreign Application Priority Data
Sep. 16, 2011 (JP) 2011-203682

(51) Int. Cl. H01L 45/00

(52) U.S. Cl. CPC H01L 45/16; H01L 45/146
USPC 438/104

(57) ABSTRACT

A method of manufacturing a nonvolatile memory element includes: forming a first conductive film above a substrate; forming, above the first conductive film, a first metal oxide layer and a second metal oxide layer having different degrees of oxygen deficiency and a second conductive film; forming a second electrode by patterning the second conductive film; forming a variable resistance layer by patterning the first metal oxide layer and the second metal oxide layer; removing a side portion of the variable resistance layer in a surface parallel to a main surface of the substrate to a position that is further inward than an edge of the second electrode; and forming a first electrode by patterning the first conductive film after or during the removing.

### TECHNICAL FIELD

The present invention is related to a variable resistance nonvolatile memory element manufacturing method and a nonvolatile memory element having a variable resistance element whose resistance value changes in response to an application of an electric pulse.

### BACKGROUND ART

With recent advances in digital technology, electronic devices such as portable information devices and home information appliances have been developed to provide higher functionality. As such, development of further miniaturized and high-speed semiconductor elements is progressing at a high pace in line with the development of higher functionality. Among these, the use of large-capacity nonvolatile memories typified by flash memory has been expanding at a rapid pace. Furthermore, as next-generation new nonvolatile memories having a potential to replace flash memory, a resistive random access memory (hereinafter also referred to as ReRAM) using a variable resistance element has been researched and developed. As defined herein, a variable resistance element refers to an element which has a characteristic in which a resistance value changes reversibly in response to electric signals and is further able to store information corresponding to the resistance value in a nonvolatile manner.

The memory element in ReRAM is a variable resistance layer which has a variable resistance value. The resistance value changes from a high resistance state to a low resistance state or vice versa in response to an application of an electric pulse (for example, a pulse voltage) to the variable resistance layer. This is how data is stored in ReRAM. For data to be stored in this method, it is necessary for two distinct values to be assigned, one for each the low resistance state and the high resistance state, and for the two values to be held in a nonvolatile manner. It is also necessary for the change between the low resistance state and the high resistance state to occur in a rapid and stable manner.

An example of a variable resistance element is a semiconductor memory device having a variable resistance region in which layers of transition metal oxide having different oxygen content atomic percentages are stacked. For example, Patent Literature (PTL) 1 discloses that variation in resistance is stabilized by causing oxidation-reduction reactions to occur at the electrode interface in contact with the variable resistance region having a high oxygen content atomic percentage.

Each of these conventional variable resistance elements includes a first electrode, a variable resistance region, and a second electrode, and are arranged two or three dimensionally to form a memory array. In each variable resistance element, the variable resistance region is a stacked structure of a first variable resistance region and a second variable resistance region comprising the same transition metal oxide. The oxygen content atomic percentage of the transition metal oxide included in the second variable resistance region is higher than the oxygen content atomic percentage of the transition metal oxide included in the first variable resistance region. With this structure, when voltage is applied to a variable resistance element, the majority of the voltage gets applied to the second variable resistance region having a higher oxygen content atomic percentage and a higher resistance value. Moreover, an abundance of oxygen capable of contributing to the reaction is present in the vicinity of the interface of the second electrode and the second variable resistance region. As such, oxidation and reduction reactions selectively occur at this interface, resulting in stabilized changes in resistance.

Directly after being produced, the transition metal oxide included in the second variable resistance region is usually an insulator. As such, it is necessary to form a localized region including a conductive filament in the variable resistance layer by performing an initial breakdown process in order to make the element capable of switching between a high resistance state and a low resistance state in response to an application of an electric pulse. It is to be noted that initial breakdown refers to a process which transforms the variable resistance element or the variable resistance nonvolatile memory element into a state which allows it to transition reversibly between a high resistance state and a low resistance state according to the voltage (or the polarity of the voltage) applied thereto. Specifically, the initial breakdown is the application of voltage (initial breakdown voltage) higher than the normal write voltage to a variable resistance element or a variable resistance nonvolatile memory element having an extremely high resistance value post-production. The initial breakdown causes the variable resistance element or the variable resistance nonvolatile memory element to enter a state in which it is capable of reversibly transitioning between a high resistance state and a low resistance state as well as decreases the resistance value thereof.

### CITATION LIST

### Patent Literature

[PTL1] WO 2008/149484

### SUMMARY OF INVENTION

### Technical Problem

A problem exists in the above-described nonvolatile memory element in which the initial breakdown voltage is high and inconsistent from variable resistance element to variable resistance element in the memory array.

An object of the present invention is to solve the above-described problem and provide a variable resistance semiconductor memory device manufacturing method in which the initial breakdown is stabilized, the time it takes to perform the initial breakdown is minimized, and in which it is possible to use a reduced initial breakdown voltage during the initial breakdown for each variable resistance element included in the memory array.

### Solution to Problem

In order to achieve the above-described goal, an aspect of the method of manufacturing a nonvolatile memory element according to the present invention includes: forming a first electrode layer above a substrate; forming a metal oxide layer on the first electrode layer, the metal oxide layer including at least a first metal oxide layer and a second metal oxide layer having different degrees of oxygen deficiency; forming a second electrode layer on the metal oxide layer; forming a second electrode by patterning the second electrode layer; forming a variable resistance layer by patterning the first metal oxide layer and the second metal oxide layer, the variable resistance layer including at least a first variable resistance layer and a second variable resistance layer having different degrees of oxygen deficiency; removing a side portion of the variable resistance layer in a surface parallel to a main surface of the substrate to a position that is further inward than an edge of the second electrode; and forming a first electrode by patterning the first electrode layer after or during the removing.

### Advantageous Effects of Invention

With the nonvolatile memory element manufacturing method according to the present invention, the effective area of the variable resistance layer can be reduced by removing the sides of the variable resistance layer in the variable resistance element including a first electrode, a second electrode, and the variable resistance layer. By reducing the effective area of the variable resistance layer, the density of the current passing through the variable resistance region increases, and a conductive path easily forms inside the variable resistance element. This allows for the reduction of the variable resistance element initial breakdown voltage and application time thereof.

### BRIEF DESCRIPTION OF DRAWINGS

FIG. 1 (a) through (j) in FIG. 1 are process diagrams showing an example of the manufacturing method of the nonvolatile memory element according to the first embodiment of the present invention.

FIG. 2 (a) through (d) in FIG. 2 are process diagrams showing an example of the manufacturing method of the nonvolatile memory element according to the second embodiment of the present invention.

FIG. 3 (a) through (d) in FIG. 3 are process diagrams showing an example of the manufacturing method of the nonvolatile memory element according to the third embodiment of the present invention.

FIG. 4 (a) through (d) in FIG. 4 are process diagrams showing an example of the manufacturing method of the nonvolatile memory element according to the fourth embodiment of the present invention.

FIG. 5 (a) through (d) in FIG. 5 are process diagrams showing an example of the manufacturing method of the nonvolatile memory element according to the fifth embodiment of the present invention.

FIG. 6 (a) through (d) in FIG. 6 are process drawings showing an example of the manufacturing method of the nonvolatile memory element according to the sixth embodiment of the present invention.

FIG. 7 (a) through (h) in FIG. 7 are process diagrams showing an example of the manufacturing method of the nonvolatile memory element according to the seventh embodiment of the present invention.

FIG. 8 (a) through (j) in FIG. 8 are process diagrams showing an example of the manufacturing method of a nonvolatile memory element according to a related invention.

FIG. 9A is a detailed view in a process diagram for a manufacturing method of a nonvolatile memory element which includes an oxidation process performed on a side portion of a conventional variable resistance element illustrating an example of an area exhibiting etching damage incurred in the side portion oxidation process.

FIG. 9B is a detailed view in a process diagram for a manufacturing method of a nonvolatile memory element which includes an oxidation process performed on a side portion of a conventional variable resistance element illustrating an example of an area exhibiting etching damage incurred in the side portion oxidation process.

FIG. 9C is a detailed view in a process diagram for a manufacturing method of a nonvolatile memory element which includes an oxidation process performed on a side portion of a conventional variable resistance element illustrating an example of an area exhibiting etching damage incurred in the side portion oxidation process.

FIG. 10 is a graph showing an example of the relationship between the oxygen concentration in the tantalum oxide TaOₓ and sheet resistivity.

### DESCRIPTION OF EMBODIMENTS

### (Underlying Knowledge Forming Basis of an Aspect of the Present Invention)

Characteristics of and a problem found by the inventors regarding a nonvolatile memory device according to an invention related to the present invention will be discussed here before discussing the embodiments of the present invention. It is to be noted that the following is intended to explain a problem which an embodiment of the present invention is designed to solve, and the present invention is not intended to be limited by the following descriptions of specific configurations, for example.

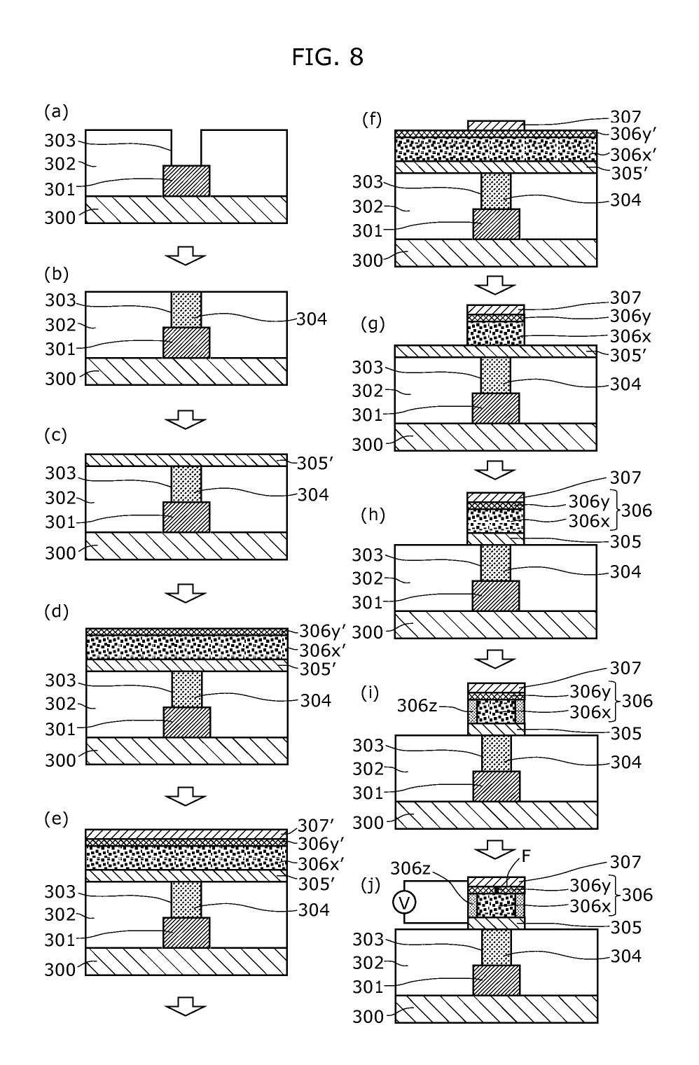

(a) through (j) in FIG. 8 are cross-sectional views showing an example of the manufacturing method of the main component of the nonvolatile memory element according to an invention related to the present invention.

First, as (a) in FIG. 8 shows, a conductive layer is formed above a substrate 300 including transistors and lower layer lines, and a lower layer line 301 is formed by patterning the conductive layer. Moreover, an interlayer insulating layer 302 is formed by forming an insulating film above the substrate 300 to cover the lower layer line 301, then planarizing the surface of the insulating film. The interlayer insulating layer 302 is then patterned using a desired mask, and a contact hole 303 penetrating the interlayer insulating layer 302 and reaching the lower layer line 301 is formed.

Next, as (b) in FIG. 8 shows, a filler material including tungsten (W) as a main component is used to fill the contact hole 303 and thereby form a contact plug 304 inside the contact hole 303.

Next, as (c) in FIG. 8 shows, a first conductive film 305′ to become a first electrode 305 is formed above the interlayer insulating layer 302 to cover the contact plug 304 by sputtering.

Next, as (d) in FIG. 8 shows, a first variable resistance film 306x′ comprising a transition metal oxide and a second variable resistance film 306y′ comprising a transition metal oxide are formed in this order above the first conductive film 305′.

Next, as (e) in FIG. 8 shows, a second conductive film 307′ to become a second electrode 307 is formed above the second variable resistance film 306y′ after the patterning process.

Next, as (f) in FIG. 8 shows, the second electrode 307 is formed by patterning the second conductive film 307′ using a desired mask.

Next, as (g) in FIG. 8 shows, a variable resistance layer 306 having a stacked structure including a first variable resistance layer 306x and a second variable resistance layer 306y is formed by patterning the first variable resistance film 306x′ and the second variable resistance film 306y′ using a desired mask.

Moreover, as (h) in FIG. 8 shows, a first electrode 305 is formed by patterning the first conductive film 305′ using a desired mask, and a variable resistance element is formed in which the variable resistance layer 306 is disposed between the first electrode 305 and the second electrode 307.

Next, as (i) in FIG. 8 shows, an insulating region 306z is formed by oxidizing the sides of the first variable resistance layer 306x by annealing the variable resistance element in an oxygen atmosphere. Since the second variable resistance layer 306y is practically an insulating layer already at this time, it is hardly oxidized by this process.

Lastly, as (j) in FIG. 8 shows, a localized region F including a conductive filament whose degree of oxygen deficiency reversibly varies according to an application of an electric pulse is formed in the second variable resistance layer 306y by applying an initial breakdown voltage to the variable resistance layer 106 via the first electrode 305 and the second electrode 307.

With this manufacturing method, by insulating the side portions of the variable resistance element by oxidization, the effective area contributing to the electrical properties of the first variable resistance layer 306x can be reduced, leak current passing through damaged areas in the variable resistance layer 306 can be reduced, and the initial breakdown voltage and application time thereof can be reduced.

It is believed that reduction of initial breakdown voltage and application time thereof is resultant from the insulation via oxidation of the region in the first variable resistance layer 306x damaged by etching, or an increase in current density as a result of the reduction in the effective area of the first variable resistance layer 306x.

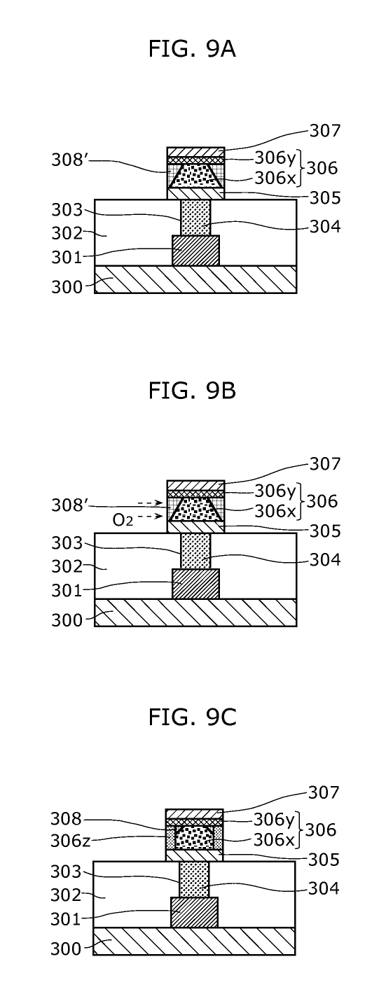

Since etching is generally carried out from the top down, it is known that the damage from etching is more prominent in the upper portion of the variable resistance layer, as is shown in FIG. 9A. On the other hand, oxidation of the side portions is uniformly performed from the outside of the variable resistance element by annealing the variable resistance element in an oxygen atmosphere, as is shown in FIG. 9B. For this reason, it becomes possible to reduce the effective area contributing to the electrical properties by oxidizing the majority of the etching damage region 308′ thereby insulating the region.

Moreover, reducing the connection surface area between the first electrode 305 and the first variable resistance layer 306x having a low resistance value as a result of the side portion oxidation is beneficial for the reduction in breakdown voltage and application time because the current density for the initial breakdown increases.

The nonvolatile memory element according to an embodiment of the present invention and the manufacturing method thereof achieves the advantageous effects that are similar to the above-described related invention, and further solves the following problem with the manufacturing method of above-described related invention.

With the variable resistance semiconductor memory device formed with the above-described process in which the side portions are oxidized, there is a problem in that the oxidation amount of the side portions cannot be easily controlled and precise estimates cannot be easily reproduced.

Difficulties with the control of the oxidation amount of the side portions will be discussed hereinafter.

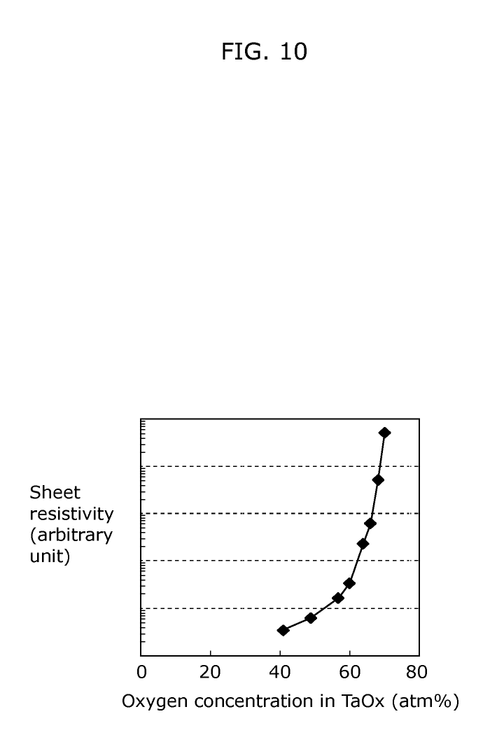

FIG. 10 shows an example of the relationship between the oxygen concentration in the tantalum oxide TaOₓ and sheet resistivity As the graph shows, the resistivity of the variable resistance element increases sharply as the oxygen concentration in the TaOₓ exceeds 60%, indicating an insulating region. When the above-described manufacturing method in which the side portions of the variable resistance element are oxidized is used, an insulating region having a high oxygen concentration forms as a result of the oxidization of the areas of the variable resistance element side portions in contact with the oxygen atmosphere. However, it is difficult to cleanly separate the insulating region of the variable resistance element side portions and the low resistance region in the variable resistance element since the oxidation gradually progresses inward from the side portions in contact with the oxygen atmosphere, forming an oxygen concentration profile which gradually slopes from the side portions to the inner portion of the variable resistance element. For this reason, high controllability of the formation of the high resistance region in the side portions of the variable resistance element is required while also preserving a low resistance region in the inner portion of the variable resistance element.

Consequently, as FIG. 9C shows, in the variable resistance semiconductor memory device formed by the above-described process of oxidizing the side portions, there is a concern that a portion of the etching damage region 308 may remain, and a concern of a possibility that the connection area between the first variable resistance layer 306x and the first electrode 305 cannot be sufficiently reduced.

An object of the nonvolatile memory element and manufacturing method thereof according to an embodiment of the present invention

is to solve the above-described problem and provide a variable resistance semiconductor memory device manufacturing method in which the initial breakdown is stabilized and in which low-voltage high-speed operation is achievable during the initial breakdown for each variable resistance element included in the memory array.

In order to achieve the above-described goal, an aspect of the method of manufacturing a nonvolatile memory element according to the present invention includes: forming a first electrode layer above a substrate; forming a metal oxide layer on the first electrode layer, the metal oxide layer including at least a first metal oxide layer and a second metal oxide layer having different degrees of oxygen deficiency; forming a second electrode layer on the metal oxide layer; forming a second electrode by patterning the second electrode layer; forming a variable resistance layer by patterning the first metal oxide layer and the second metal oxide layer, the variable resistance layer including at least a first variable resistance layer and a second variable resistance layer having different degrees of oxygen deficiency; removing a side portion of the variable resistance layer in a surface parallel to a main surface of the substrate to a position that is further inward than an edge of the second electrode; and forming a first electrode by patterning the first electrode layer after or during the removing.

Moreover, in the forming of a first electrode, the first electrode may be formed to have a profile larger than a profile of the variable resistance layer when observed from a direction perpendicular to the main surface of the substrate.

With this manufacturing method, during the initial breakdown, the electric field concentrates in the narrowed region remaining after the removal of the side portions of the variable resistance layer, and the conductive path of the variable resistance element forms at the narrowed region. With this, it is possible to increase the density of the current passing through the variable resistance region. Furthermore, since removal of the side portions of the variable resistance layer directly results in the removal of the portion damaged by etching, it becomes possible to reduce the leak current passing through the etching damage region. The above makes it possible to reduce initial breakdown voltage and application time thereof with respect to each variable resistance element in the memory array, and leads to a reduction in variable resistance characteristic inconsistency.

Moreover, the forming of a variable resistance layer and the removing may be performed in a single etching process at once.

With this, manufacturing time and cost can be reduced since the number of processes performed is reduced.

Moreover, the forming of a first electrode and the removing may be performed in a single etching process at once.

With this, manufacturing time and cost can be reduced since the number of processes performed is reduced. Furthermore, etching can be carried out in accordance with the mask dimensions thereby preventing the contact plug for becoming exposed.

Moreover, in the removing, the side portion of the variable resistance layer may be removed by wet etching.

Generally, when patterning by etching the variable resistance layer interposed between the first electrode and the second electrode, the sides of the variable resistance layer incur damage which leads to the degradation of electrical properties and variable resistance characteristic of the variable resistance element. The damaged low oxygen concentration portion formed in the variable resistance layer as a result of the etching can be selectively etched with wet etching. As such, the degradation of electrical properties and variable resistance characteristics of the variable resistance elements in the memory array can be reduced.

Moreover, the forming of a metal oxide layer may include forming the first metal oxide layer on the first electrode layer and forming the second metal oxide layer on the first metal oxide layer, and in the removing, the first variable resistance layer may be formed to have a cross-sectional surface area in a plane parallel to the main surface of the substrate that is larger than a cross-sectional surface area of the second variable resistance layer in a plane parallel to the main surface of the substrate.

Generally, etching damage incurred when the variable resistance layer interposed between the first electrode and the second electrode is patterned is extensive in the upper portion of the variable resistance layer. With this configuration, since the upper portion of the variable resistance element sustaining etching damage deep into the variable resistance layer is selectively removed, degradation of electrical properties and variable resistance characteristics of the variable resistance elements in the memory array can be reduced.

Moreover, the forming of a metal oxide layer includes forming the first metal oxide layer on the first electrode layer and forming the second metal oxide layer on the first metal oxide layer, and in the removing, the first variable resistance layer may be formed to have a cross-sectional surface area in a plane parallel to the main surface of the substrate that is smaller than a cross-sectional surface area of the second variable resistance layer in a plane parallel to the main surface of the substrate.

With this, since it is possible to narrow the region of the second metal oxide layer in which the conductive path can be formed, variable resistance characteristic inconsistency in each variable resistance element in the memory array can be further reduced.

Moreover, in the forming of a metal oxide layer, each of the first metal oxide layer and the second metal oxide layer may comprise a transition metal oxide or aluminum oxide.

Moreover, in the forming of a metal oxide layer, the transition metal oxide may be tantalum oxide, hafnium oxide, or zirconium oxide.

Since these materials excel in terms of retention characteristics and allow for high-speed operation, the above results, that is to say, reduction of the initial breakdown voltage, application time of the breakdown voltage, and variable resistance characteristic inconsistency, can be realized, especially in a nonvolatile memory element performing stable, high-speed resistance changing operations.

Moreover, the first metal oxide layer and the second metal oxide layer may comprise a same constituent metal.

Moreover, the first metal oxide layer and the second metal oxide layer may comprise different constituent metals.

With this, the above results, that is to say, reduction of the initial breakdown voltage, application time of the breakdown voltage, and variable resistance characteristic inconsistency, can be realized in the nonvolatile memory element in which materials suitable for each the first metal oxide layer and the second metal oxide layer are used.

Moreover, the method may further include forming, in the variable resistance layer, by application of a first electric pulse to the variable resistance layer, a region having a resistance value that changes reversibly in response to an application of (i) a second electric pulse having a first polarity and having an amplitude that is smaller than an amplitude of the first electric pulse, or (ii) a third electric pulse having a second polarity that is different from the first polarity and having an amplitude that is smaller than the amplitude of the first electric pulse.

Moreover, the region having the resistance value that changes reversibly may be a localized region that includes a conductive filament and is formed in a less oxygen deficient one of the first variable resistance layer and the second variable resistance layer, and the localized region may have a degree of oxygen deficiency that changes reversibly in response to the second electric pulse or the third electric pulse.

With this, a nonvolatile memory element can be realized which performs operations effectively as ReRAM.

Moreover, an aspect of the nonvolatile memory element according to the present invention may include: a first electrode; a second electrode; and a variable resistance layer interposed between the first electrode and the second electrode and having a resistance value that changes reversibly based on an electric signal applied between the first electrode and the second electrode, wherein the variable resistance layer includes at least a first variable resistance layer comprising a first metal oxide and a second variable resistance layer comprising a second metal oxide, the first metal oxide and the second metal oxide having different degrees of oxygen deficiency, and a side portion of the variable resistance layer is recessed inward of an edge of the second electrode in a surface parallel to a main surface of the substrate.

With this configuration, during the initial breakdown, the electric field concentrates in the narrowed region remaining after the removal of the side portions of the variable resistance layer, and it is possible to increase the density of the current passing through the variable resistance region since the conductive path of the variable resistance element forms at the narrowed region. Furthermore, since removal of the side portions of the variable resistance layer directly results in the removal of the portion damaged by etching, it becomes possible to reduce the leak current passing through the etching damage region.

Hereinafter, embodiments of the nonvolatile memory element and manufacturing method of the same according to the present invention will be described with reference to the drawings. It is to be noted that each of the embodiments described below shows a specific example of the present invention. The numerical values, shapes, materials, structural elements, the arrangement and connection of the structural elements, steps, the processing order of the steps etc. shown in the following exemplary embodiments are mere examples, and therefore do not limit the present invention. Moreover, among the structural elements in the following exemplary embodiments, structural elements not recited in any one of the independent claims defining the most generic part of the inventive concept are described as structural elements of a preferable embodiment. The constituents designated by the same reference numerals throughout the drawings will not be described repetitively in some cases. In addition, in the drawings, the constituents are schematically depicted for easier understanding. Therefore, the shapes and scales of the constituents are not depicted accurately.

### First Embodiment

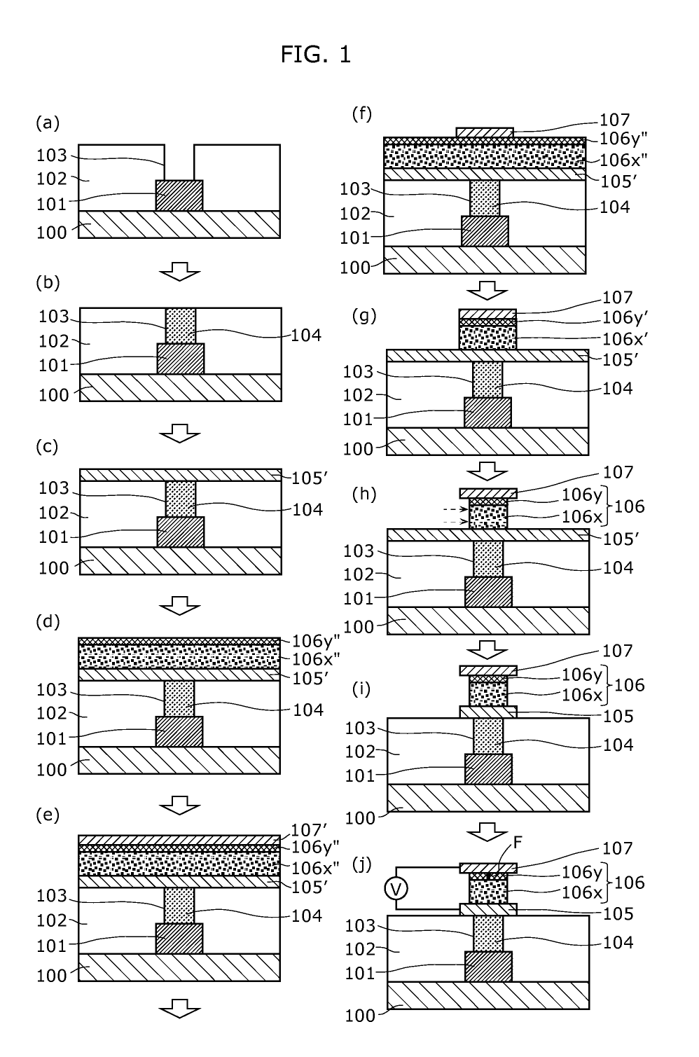

First, as (a) in FIG. 1 shows, a conductive layer (having a film thickness between, for example, 400 nm and 600 nm, inclusive) comprising aluminum, etc. is formed above a substrate 100 including transistors and lower layer lines, and a lower layer line 101 is formed by patterning the conductive layer.

Next, an interlayer insulating layer 102 (having a film thickness between, for example, 500 nm and 1000 nm, inclusive) is formed by forming an insulating film above the substrate 100 to cover the lower layer line 101, then planarizing the surface of the insulating film. A plasma tetraethyl orthosilicate (TEOS) film along with a fluorinated oxide (for example, fluorinated silicate glass (FSG)) and other low-k materials to reduce parasitic capacitance between wires are used for the interlayer insulating layer 102.

The interlayer insulating layer 102 is then patterned using a desired mask, and a contact hole 103 (having a diameter between, for example, 50 nm and 300 nm, inclusive) penetrating the interlayer insulating layer 102 and reaching the lower layer line 101 is formed.

Here, the width of the lower layer line 101 may be made larger than the diameter of the contact hole 103. This prevents the area of contact between the lower layer line 101 and the contact plug 104 from changing due to mask misalignment. One result of this is that cell current fluctuation can be controlled, for example.

Next, as (b) in FIG. 1 shows, a lower layer which is a titanium nitride (TiN)/titanium layer (Ti) (having a film thickness between, for example, 5 nm and 30 nm, inclusive) functioning as an adhesive layer and a diffusion barrier is formed by sputtering, and an upper layer mainly comprising tungsten (having a film thickness between 200 nm and 400 nm, inclusive) is formed by CVD. As a result, the contact hole 103 is filled with a filler material mainly comprising tungsten. Next, the entire wafer surface is planarized using chemical mechanical polishing (CMP) whereby unwanted filler material is removed from the surface of the interlayer insulating layer 102, and a contact plug 104 is formed in the contact hole 103 above the substrate 100.

Next, as (c) in FIG. 1 shows, a first conductive film 105′ (having a thickness between, for example, 50 nm and 200 nm, inclusive) comprising a noble metal (platinum (Pt), iridium (Ir), palladium (Pd), etc.) which will become a first electrode 105 is formed above the interlayer insulating layer to cover the contact plug by sputtering. Here, the first conductive film 105′ is an example of the first electrode layer.

Next, as (d) in FIG. 1 shows, a variable resistance film including multiple layers each having different oxygen content atomic percentages, that is to say, a first variable resistance film 106x″ comprising a metal oxide and a second variable resistance film 106y″ comprising a metal oxide are formed in this order above the first conductive film 105′. Here, the first variable resistance film 106x″ and the second variable resistance film 106y″ are examples of the first metal oxide layer and the second metal oxide layer, respectively.

As conditions for achieving preferable variable resistance characteristics, the first variable resistance film 106x″ may have an oxygen content atomic percentage between 50 atm % and 65 atm %, inclusive, a resistivity between 2 mΩ-cm and 50 mΩ-cm, inclusive, and a film thickness between 20 nm and 100 nm, inclusive. Likewise, the second variable resistance film 106y″ may have an oxygen content atomic percentage between 65 atm % and 75 atm %, inclusive, a resistivity of 10⁷ mΩ-cm and up, and a film thickness between 3 nm and 10 nm, inclusive.

Here, a method of sputtering a tantalum target in a mixed gas atmosphere of argon (Ar) and oxygen (O₂), in other words, a reactive sputtering method is used to form the first variable resistance film 106x″ and the second variable resistance film 106y″. As a result, the first variable resistance film 106x″ is a low resistance film having a lower oxygen concentration than the second variable resistance film 106y″.

Next, as (e) in FIG. 1 shows, a second conductive film 107′ comprising a noble metal (platinum (Pt), iridium (Ir), palladium (Pd), etc.) to become a second electrode 107 is formed above the second variable resistance film 107y″ after the patterning process. Here, the second conductive film 107′ is an example of the second electrode layer.

Next, as (f) in FIG. 1 shows, the second electrode 107 is formed by patterning the second conductive film 107′ using a desired mask. A mixed gas atmosphere of Ar and O₂, for example, may be used for the etching in the patterning process.

Next, as (g) in FIG. 1 shows, the first variable resistance film 106x″ and the second variable resistance film 106y″ are patterned using a desired mask. For example, a variable resistance film may be patterned using the second electrode 107 as a mask, which comprises a material that is resistive to etching. The patterned variable resistance film forms the first variable resistance layer 106x′ and the second variable resistance layer 106y′.

It is preferable that this process is performed under the condition that the first conductive film 105′ to become the first electrode 105 is resistive to the etching in the patterning of the variable resistance film. The first variable resistance film 106x″ and the second variable resistance film 107y″ may be etched, for example, in a mixed gas including a fluorine compound. This is because the greater the thickness of the remaining first conductive film 105′, the more efficiently it can function as an oxygen diffusion barrier.

Here, the first variable resistance layer 106x (first variable resistance film 106x″) comprises a first metal oxide, such as a metal oxide having an oxygen deficient tantalum oxide (TaOₓ, 0<x<2.5) as a main component. The oxygen content atomic percentage of the second metal oxide in the second variable resistance layer 106y (second variable resistance film 106y″) is higher than the oxygen content atomic percentage of the first metal oxide in the first variable resistance layer 106x. In other words, the degree of oxygen deficiency of the second metal oxide is lower than the degree of oxygen deficiency of the first metal oxide.

The degree of oxygen deficiency is a rate of oxygen deficiency relative to the amount of oxygen included in a metal oxide having a stoichiometric composition (the stoichiometric composition having the highest resistance value when multiple stoichiometric compositions are present). A metal oxide having a stoichiometric composition is more stable and has a higher resistance value than a metal oxide having a non-stoichiometric composition.

For example, when the metal is tantalum (Ta), the composition is expressed as TaO_{2.5} since the stoichiometric oxide composition, as defined above, is Ta₂O₅. The degree of oxygen deficiency of TaO_{2.5} is 0%, so the degree of oxygen deficiency of TaO_{1.5} is 40% ((2.5−1.5)/2.5=40%). Moreover, a metal oxide having excess oxygen atoms has a negative degree of oxygen deficiency. It is to be noted that within the present Specification, unless otherwise noted, the degree of oxygen deficiency includes positive values, 0, and negative values.

An oxide having a low degree of oxygen deficiency has a high resistance value since it is closer to an oxide having a stoichiometric composition, and an oxide having a high degree of oxygen deficiency has a low resistance value since it is closer to a metal comprising an oxide.

Moreover, the oxygen content atomic percentage is a ratio of the number of oxygen atoms to total number of atoms. For example, the oxygen content atomic percentage of Ta₂O₅ is 71.4 atm %, which is the ratio of the number of oxygen atoms to the total number of atoms (O/(Ta+O)). Thus, an oxygen-deficient tantalum oxide has an oxygen content atomic percentage that is greater than 0 and less than 71.4 atm %. For example, when the first metal oxide included in the first variable resistance layer 106x and the second metal oxide included in the second variable resistance layer 106y comprise the same constituent metal, the oxygen content atomic percentage corresponds with the degree of oxygen deficiency. That is to say, when the oxygen content atomic percentage of the second metal oxide is greater than the oxygen content atomic percentage of the first metal oxide, the degree of oxygen deficiency of the second metal oxide is less than the degree of oxygen deficiency of the first metal oxide.

A metal other than tantalum may be used for the variable resistance layer 106. A transition metal or aluminum (Al) can be used for the variable resistance layer 106. Tantalum (Ta), titanium (Ti), hafnium (Hf), zirconium (Zr), niobium (Nb), tungsten (W), etc., may be used as the transition metal. Since transition metals can assume many different oxidation states, it is possible to achieve different resistance states through oxidation-reduction reactions.

For example, it has been confirmed that the resistance value of the variable resistance layer 106 can be changed at high-speed and in a stable manner when hafnium oxide is used and the composition of the first variable resistance layer 106x is HfOₓ where x is between 0.9 and 1.6, inclusive, and the composition of the second variable resistance layer 106y is HfO_{y} where y is greater than x. In this case, the film thickness of the second variable resistance layer 106y may be between 3 nm and 4 nm, inclusive.

Moreover, it has been confirmed that the resistance value of the variable resistance layer 106 can be changed at high-speed and in a stable manner when zirconium oxide is used and the composition of the first variable resistance layer 106x is ZrOₓ where x is between 0.9 and 1.4, inclusive, and the composition of the second variable resistance layer 106y is ZrO_{y} where y is greater than x. In this case, the film thickness of the second variable resistance layer 106y may be between 1 nm and 5 nm, inclusive.

It is to be noted that the first metal included in the first metal oxide to become the first variable resistance layer 106x and the metal included in the second metal oxide to become the second variable resistance layer 106y may be different metals. In this case, the degree of oxygen deficiency of the second variable resistance layer 106y may be less than the degree of oxygen deficiency of the first variable resistance layer 106x, in other words, the resistivity of the second variable resistance layer 106y may be higher. By adopting such a configuration, the voltage applied between the first electrode 105 and the second electrode 107 during a resistance change is distributed to the second variable resistance layer 106y in majority, thereby allowing the oxidation-reduction reactions to occur more easily in the second variable resistance layer 106y.

Moreover, when different metals are used for the first and second metals, the second metal may have a standard electrode potential that is lower than the standard electrode potential of the first metal. The higher the standard electrode potential, the less tendency a metal has to be oxidized. As such, oxidation-reduction reactions can occur relatively easily in the second metal oxide having a relatively low standard electrode potential. This is because it is believed that the resistance changing phenomenon occurs (the resistance value (degree of oxygen deficiency) changes) as oxidation-reduction reactions occur in the fine filament (conductive path) formed inside the high-resistance second variable resistance layer 106y.

For example, by using oxygen-deficient tantalum oxide in the first variable resistance layer 106x and titanium oxide (TiO₂) in the second variable resistance layer 106y, a stable resistance changing operation can be achieved. Titanium (standard electrode potential=−1.63 eV) has a lower standard electrode potential than tantalum (standard electrode potential=−0.6 eV). The higher the standard electrode potential, the less tendency a metal has to be oxidized.

Oxidation-reduction reactions can be made to occur more easily in the second variable resistance layer 106y by using a metal oxide having a lower standard electrode potential than the first variable resistance layer 106x. As an example of other possible compositions, oxygen-deficient tantalum oxide (Ta Oₓ) may be used in the first variable resistance layer 106x, and aluminum oxide (Al₂O₃) may be used in the second variable resistance layer 106y.

It is to be noted that, as previously explained, since the resistance changing phenomenon occurs in the variable resistance layer which includes an oxygen deficient metal oxide as a result of the transfer of oxygen, it is acceptable if different constituent metals are used so long as the transfer of oxygen is possible as a minimum requirement. As such, a variable resistance layer which can stably perform resistance changing operations can be achieved even when the first metal included in the first variable resistance layer 106x and the second metal included in the second variable resistance layer 106y are different metals.

Next, the manufacturing method of the nonvolatile memory element will be explained.

As (h) in FIG. 1 shows, the first variable resistance layer 106x and the second variable resistance layer 106y are formed by removing, via etching, the etching-damaged side portions of the first variable resistance layer 106x′ and the second variable resistance layer 106y′ of the patterned variable resistance element.

A mixed gas including a halogen gas, which is highly reactive with TaOₓ, may be used for the etching process to remove the side portions, such as a mixed gas of Cl₂ and BCl₃, for example. Moreover, etching may be performed at a higher than conventional etching temperature, for example, at a temperature between 200 and 300 degrees Celsius, inclusive. By using a high-temperature etching process to increase the etching speed and the reactivity of the halogen gas, the side portions of the first variable resistance layer 106x and the second variable resistance layer 106y of the variable resistance element can be more easily etched.

In this case, etching will not be performed beyond the first conductive film 105′ since the first conductive film 105′ comprises a noble metal (platinum (Pt), iridium (Ir), palladium (Pd), etc.) having a high etching selection ratio to TaOₓ. As a result, the amount of removal of the side portions can be accurately adjusted since the process of removing the side portions of the variable resistance layer can be performed independently.

Next, as (i) in FIG. 1 shows, the first conductive film 105′ is patterned using a desired mask, such as the second electrode 107, and the first electrode 105 is formed connected to the contact plug 104 from the patterned first conductive film 105′.

It is preferable that this process is performed under the condition that the side portions of the variable resistance layer are not etched. For example, the etching may be performed using a mixed gas including Ar and O₂. With the mixed gas of Ar and O₂, the side portions of the TaOₓ are, for the most part, not etched; only the first electrode is etched.

It is to be noted that in (i) in FIG. 1, the size relationship of the first electrode 105 and the variable resistance layer 106 is such that the profile of the first electrode 105 appears larger than the profile of the variable resistance layer 106 when observed from a direction perpendicular to the main surface of the substrate 100, but this size relationship is not limited thereto.

As a result of these processes, a variable resistance element in which the variable resistance layer 106 is disposed between the first electrode 105 and the second electrode 107 is formed.

The nonvolatile memory element according to the first embodiment of the present invention can be realized by thereafter performing the usual processes of covering the variable resistance element with an interlayer insulating film, forming a contact plug connected to the second electrode of the variable resistance element, and forming an upper layer line connected to the contact plug, for example (not in Drawings).

Lastly, as (j) in FIG. 1 shows, a localized region F including a conductive filament whose degree of oxygen deficiency reversibly varies according to an application of an electric pulse used for changing resistance is formed in the second variable resistance layer 106y by applying an initial breakdown voltage having an amplitude with an absolute value higher than the voltage normally used for changing resistance to the variable resistance layer 106 via the first electrode 105 and the second electrode 107.

With the above manufacturing method, the sides of the variable resistance layer 106 are removed via etching before the formation of the first electrode 105 in the manufacturing process of the variable resistance element including the second electrode 107, the variable resistance layer 106, and the first electrode 105 formed above the contact plug 104. As a result, the effective area of the variable resistance layer which contributes to the electrical properties can be reduced, and the initial breakdown voltage and application time thereof can be reduced.

### Second Embodiment

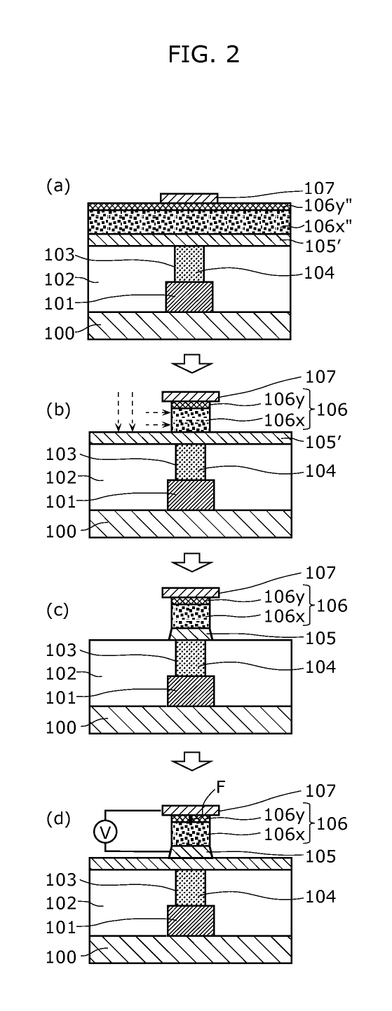

(a) through (d) in FIG. 2 are cross-sectional views showing the manufacturing method of a main component of the nonvolatile memory element according to the second embodiment of the present invention. The reference numerals for the constituents in (a) through (d) in FIG. 2 are the same as those in (a) through (j) in FIG. 1, and as such, explanations thereof will be omitted.

As (a) through (d) in FIG. 2 show, the difference between the manufacturing method of the nonvolatile memory element according to the first embodiment of the present invention and the manufacturing method of the nonvolatile memory element according to the second embodiment of the present invention is that in the latter, the process of patterning the variable resistance film 106x″ and second variable resistance film 107y″ shown in (g) and (h) in FIG. 1 and the process of removing the side portions of the variable resistance element are performed at the same time.

In contrast to the manufacturing method of the nonvolatile memory element according to the first embodiment of the present invention in which the variable resistance layer 106 is formed by removing the sides of the variable resistance layer after patterning the variable resistance film 106x″, with the manufacturing method of the nonvolatile memory element according to the second embodiment of the present invention, the process of patterning the variable resistance layer 106 and the process of removing the side portions of the variable resistance element are performed at the same time, in the same process. Consequently, since the processes before (a) in FIG. 2 are the same as those in (a) through (f) in FIG. 1, explanations thereof will be omitted.

Next, as (b) in FIG. 2 shows, the first variable resistance film 106x″, the second variable resistance film 107y″, and the first conductive film 105′ are patterned using a desired mask. At that time, the first variable resistance layer 106x, the second variable resistance layer 106y, and the first electrode 105 are formed by etching the side portions of the first variable resistance layer and the second variable resistance layer in the variable resistance element at the same time as the patterning process.

It is preferable that this process is performed under the condition that etching can be performed on the side portions of the first variable resistance film 106x″, the second variable resistance film 107y″, and the variable resistance layer 106. Etching may be performed in a mixed gas including a halogen gas, such as a mixed gas of Cl₂ and BCl₃, for example. Moreover, etching may be performed at a higher than conventional etching temperature, for example, at a temperature between 200 and 300 degrees Celsius, inclusive. By using a high-temperature etching process to increase the etching speed and the reactivity of the halogen gas, the side portions of the first variable resistance layer 106x and the second variable resistance layer 106y of the variable resistance element can be more easily etched at the same time as the patterning process.

Next, as (c) in FIG. 2 shows, the first conductive film 105′ is patterned using a desired mask, such as the second electrode 107, and the first electrode 105 is formed connected to the contact plug 104 from the patterned first conductive film 105′.

It is preferable that this process is performed under the condition that the side portions of the variable resistance layer are not etched. For example, the etching may be performed using a mixed gas including Ar and O₂. With the mixed gas of Ar and O₂, the side portions of the TaOₓ are, for the most part, not etched.

It is to be noted that in (c) in FIG. 2, the size relationship of the first electrode 105 and the variable resistance layer 106 is such that the profile of the first electrode 105 appears to be the same size as the profile of the variable resistance layer 106 when observed from a direction perpendicular to the main surface of the substrate 100, but this size relationship is not limited thereto. For example, the first electrode 105 may be formed such that an edge thereof is further inward than an edge of the variable resistance layer 106 when observed from a direction perpendicular to the main surface of the substrate 100.

As a result of these processes, a variable resistance element in which the variable resistance layer 106 is disposed between the first electrode 105 and the second electrode 107 is formed.

The nonvolatile memory element according to the second embodiment of the present invention can be realized by thereafter performing the usual processes of covering the variable resistance element with an interlayer insulating film, forming a contact plug connected to the second electrode of the variable resistance element, and forming an upper layer line connected to the contact plug, for example (not in Drawings).

Lastly, as (d) in FIG. 2 shows, a localized region F including a conductive filament whose degree of oxygen deficiency reversibly varies according to an application of a positive or negative electric pulse used for changing resistance is formed in the second variable resistance layer 106y by applying an initial breakdown voltage to the variable resistance layer 106 via the first electrode 105 and the second electrode 107.

With the above manufacturing method, the sides of the variable resistance layer 106 are removed via etching before the formation of the first electrode 105 in the manufacturing process of the variable resistance element including the second electrode 107, the variable resistance layer 106, and the first electrode 105 formed above the contact plug 104. As a result, the effective area of the variable resistance layer which contributes to the electrical properties can be reduced, and the initial breakdown voltage and application time thereof can be reduced.

Furthermore, compared to the nonvolatile memory element according to the first embodiment of the present invention, nonvolatile memory element manufacturing costs can be cut due to the ability to omit the process of patterning the variable resistance film 106x″ and the second variable resistance film 107y″ shown in (g) in FIG. 1 with the nonvolatile memory element according to the second embodiment of the present invention formed with the above-described manufacturing method.

### Third Embodiment

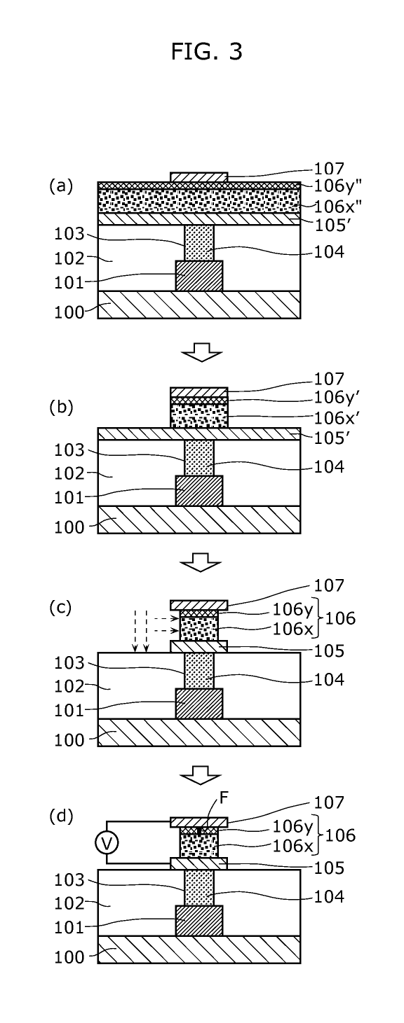

(a) through (d) in FIG. 3 are cross-sectional views showing the manufacturing method of a main component of the nonvolatile memory element according to the third embodiment of the present invention. The reference numerals for the constituents in (a) through (d) in FIG. 3 are the same as those in (a) through (j) in FIG. 1, and as such, explanations thereof will be omitted.

As (a) through (d) in FIG. 3 show, the difference between the manufacturing method of the nonvolatile memory element according to the first embodiment of the present invention and the manufacturing method of the nonvolatile memory element according to the third embodiment of the present invention is that in the latter, the process of removing the sides of the variable resistance film 106x″ and second variable resistance film 107y″ shown in (h) and (i) in FIG. 1 and the process of patterning the first conductive film 105′ are performed at the same time.

In contrast to the manufacturing method of the nonvolatile memory element according to the first embodiment of the present invention in which the first conductive film 105′ is patterned and the patterned first conductive film 105′ is formed as the first electrode 105 connected to the contact plug 104 after patterning the variable resistance film 106x″ and removing the sides of the variable resistance layer, that is, after formation of the variable resistance layer 106, with the manufacturing method of the nonvolatile memory element according to the third embodiment of the present invention, the process of removing the side portions of the variable resistance layer 106 and the process of patterning the first conductive film 105′ are performed at the same time. Consequently, since the processes before (b) in FIG. 3 are the same as those in (a) through (g) in FIG. 1, explanations thereof will be omitted.

However, in the third embodiment according to the present invention, the first conductive film 105′, which covers the contact plug 104 shown in (c) in FIG. 1 and later becomes the first electrode 105, comprises tantalum nitride.

As (c) in FIG. 3 shows, the first variable resistance film 106x′, the second variable resistance film 107y′, and the first conductive film 105′ are patterned using a desired mask. For example, a variable resistance film may be patterned using the second electrode 107 as a mask, which comprises a material that is resistive to etching. At that time, the first variable resistance layer 106x, the second variable resistance layer 106y, and the first electrode 105 are formed by etching the side portions of the first variable resistance layer and the second variable resistance layer in the variable resistance element at the same time as the patterning process.

It is preferable that this process is performed under the condition that the first electrode 105 and the side portions of first variable resistance film 106x′, the second variable resistance film 107y′, and the variable resistance layer 106 can be etched. Etching may be performed in a mixed gas including a halogen gas, such as a mixed gas of Cl₂ and BCl₃, for example. Moreover, etching may be performed at a higher than conventional etching temperature, for example, at a temperature between 200 and 300 degrees Celsius, inclusive. By using a high-temperature etching process to increase the etching speed and the reactivity of the halogen gas, the side portions of the first variable resistance layer 106x and the second variable resistance layer 106y of the variable resistance element can be more easily etched at the same time as the patterning process.

Since the mask used in the etching is the second electrode 107 and the dimensions of the first electrode 105 are determined by dimensions of the second electrode 107, the first electrode 105 can be formed to be sufficiently big compared to the contact dimensions, and the possibility of the contact plug becoming exposed can be reduced.

As a result of these processes, a variable resistance element in which the variable resistance layer 106 is disposed between the first electrode 105 and the second electrode 107 is formed.

The nonvolatile memory element according to the third embodiment of the present invention can be realized by thereafter performing the usual processes of covering the variable resistance element with an interlayer insulating film, forming a contact plug connected to the second electrode of the variable resistance element, and forming an upper layer line connected to the contact plug, for example (not in Drawings).

Lastly, as (d) in FIG. 3 shows, a localized region F including a conductive filament whose degree of oxygen deficiency reversibly varies according to an application of a positive or negative electric pulse used for changing resistance is formed in the second variable resistance layer 106y by applying an initial breakdown voltage to the variable resistance layer 106 via the first electrode 105 and the second electrode 107.

With the above manufacturing method, the sides of the variable resistance layer 106 are removed via etching before the formation of the first electrode 105 in the manufacturing process of the variable resistance element including the second electrode 107, the variable resistance layer 106, and the first electrode 105 formed above the contact plug 104. As a result, the effective area of the variable resistance layer which contributes to the electrical properties can be reduced, and the initial breakdown voltage and application time thereof can be reduced.

Furthermore, compared to the nonvolatile memory element according to the first embodiment of the present invention, nonvolatile memory element manufacturing costs can be cut due to the ability to omit the process of patterning the variable resistance film 106x″ shown in (g) in FIG. 1 with the nonvolatile memory element according to the third embodiment of the present invention formed with the above-described manufacturing method.

### Fourth Embodiment

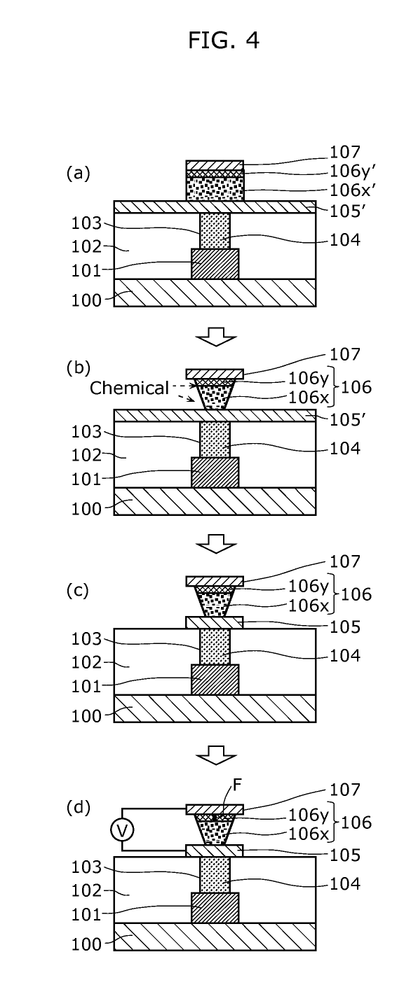

(a) through (d) in FIG. 4 are cross-sectional views showing the manufacturing method of a main component of the nonvolatile memory element according to the fourth embodiment of the present invention. The reference numerals for the constituents in (a) through (d) in FIG. 4 are the same as those in (a) through (j) in FIG. 1, and as such, explanations thereof will be omitted.

As (a) through (d) in FIG. 4 show, the difference between the manufacturing method of the nonvolatile memory element according to the first embodiment of the present invention and the manufacturing method of the nonvolatile memory element according to the fourth embodiment of the present invention is that in the latter, wet etching is used in the process of removing the side portions of the variable resistance layer.

In contrast to the manufacturing method of the nonvolatile memory element according to the first embodiment of the present invention in which the process of etching the sides of the first variable resistance layer 106x and the second variable resistance layer 106y is performed at the same time as the patterning of the variable resistance film 106x″, that is, at the same time as the formation of the variable resistance layer 106, the first variable resistance layer 106x and the second variable resistance layer 106y are formed by wet etching the sides of the first variable resistance layer 106x′ and the second variable resistance layer 106y′ after the variable resistance layer 106x′ is formed with the manufacturing method of the nonvolatile memory element according to the fourth embodiment of the present invention Consequently, since the processes before (a) in FIG. 4 are the same as those in (a) through (g) in FIG. 1, explanations thereof will be omitted.

As (b) in FIG. 4 shows, the first variable resistance layer 106x and the second variable resistance layer 106y are formed by wet etching, with buffered hydrofluoric acid, the side portions of the first variable resistance layer 106x′ and the second variable resistance layer 106y′ of the patterned variable resistance element. In this case, the selectivity of a high oxygen concentration TaOₓ with respect to the buffered hydrofluoric acid is relatively higher than a low oxygen concentration TaOₓ. In other words, a high oxygen concentration TaOₓ is more resistive to etching. As such, the variable resistance layer 106 is formed having an inverted tapered shape, as (b) in FIG. 4 shows.

Finally, as (c) in FIG. 4 shows, the first electrode 105 is formed by patterning the first conductive film 105′ using a desired mask, such as the second electrode 107, for example.

Under the condition that the sides of the variable resistance layer are resistive to etching, a mixed gas atmosphere of Ar and O₂, for example, may be used for the etching in the patterning process. With the mixed gas of Ar and O₂, the side portions of the TaOₓ are, for the most part, not etched. As a result of these processes, a variable resistance element in which the variable resistance layer 106 is disposed between the first electrode 105 and the second electrode 107 is formed.

The nonvolatile memory element according to the fourth embodiment of the present invention can be realized by thereafter performing the usual processes of covering the variable resistance element with an interlayer insulating film, forming a contact plug connected to the second electrode of the variable resistance element, and forming an upper layer line connected to the contact plug, for example (not in Drawings).

Lastly, as (d) in FIG. 4 shows, a localized region F including a conductive filament whose degree of oxygen deficiency reversibly varies according to an application of an electric pulse is formed in the second variable resistance layer 106y by applying an initial breakdown voltage to the variable resistance layer 106 via the first electrode 105 and the second electrode 107. By forming the variable resistance layer 106 to have an inverted tapered shape, the localized region F including the conductive filament is formed in the vicinity of the center of the second variable resistance layer 106y′ and a stable change in resistance can be achieved as a result of the current path of the variable resistance layer 106 being restricted to the center thereof.

With the above manufacturing method, the sides of the variable resistance layer 106 are removed via etching before the formation of the first electrode 105 in the manufacturing process of the variable resistance element including the second electrode 107, the variable resistance layer 106, and the first electrode 105 formed above the contact plug 104. As a result, the effective area of the variable resistance layer which contributes to the electrical properties can be reduced, and the initial breakdown voltage and application time thereof can be reduced.

Furthermore, since the sides of the variable resistance layer are removed using a wet etching process, compared to the nonvolatile memory element according to the first embodiment of the present invention, the nonvolatile memory element according to the fourth embodiment of the present invention formed with the above-described manufacturing method allows for a greater reduction in the degradation of electrical properties and variable resistance characteristics of the variable resistance element resulting from etching damage, since the etching damage portion having a low degree of oxygen concentration is preferentially selectively removed.

### Fifth Embodiment

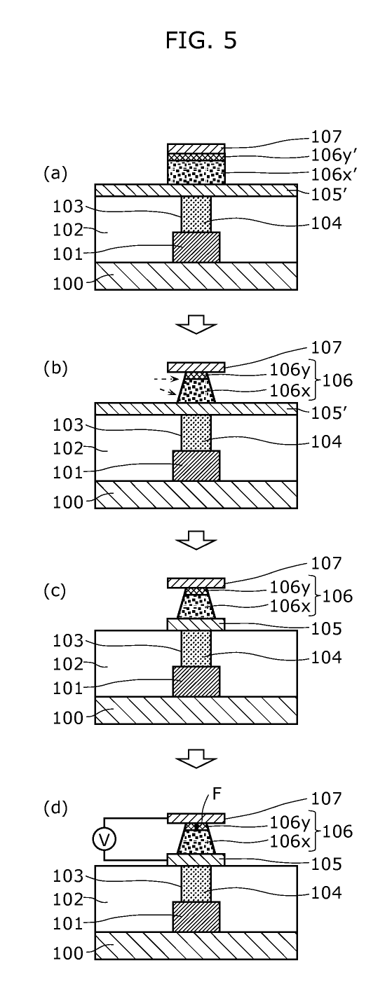

(a) through (c) in FIG. 5 are cross-sectional views showing the manufacturing method of a main component of the nonvolatile memory element according to the fifth embodiment of the present invention. The reference numerals for the constituents in (a) through (c) in FIG. 5 are the same as those in (a) through (i) in FIG. 1, and as such, explanations thereof will be omitted.

As (a) through (c) in FIG. 5 show, the difference between the manufacturing method of the nonvolatile memory element according to the first embodiment of the present invention and the manufacturing method of the nonvolatile memory element according to the fifth embodiment of the present invention is that in the latter, the surface area of the portion of the first metal oxide layer connected to the first electrode is formed to be larger than the surface area of the portion of the second metal oxide layer connected to the second electrode, and the second metal oxide layer has a higher oxygen content atomic percentage than the first metal oxide layer. Consequently, since the processes before (a) in FIG. 5 are the same as those in (a) through (g) in FIG. 1, explanations thereof will be omitted.

First, as (b) in FIG. 5 shows, the first variable resistance layer 106x and the second variable resistance layer 106y are formed by etching the side portions of the first variable resistance layer and the second variable resistance layer at the same time as the formation of the variable resistance layer 106.

It is preferable that this process is performed under the condition that the side portions of the variable resistance layer 106 can easily be etched and that the variable resistance layer 106 is formed to have a tapered shape. Etching may be performed in a mixed gas including a halogen gas, such as a mixed gas of Cl₂ and BCl₃, which is highly reactive with TaOₓ, and nitrogen (N₂), for example. This is because adding N₂ to the etching gas has the effect of preserving the walls of the element, and creates a difference in the rate of progression of etching between the upper and lower portions of the element.

Moreover, etching may be performed at a higher than conventional etching temperature, for example, at a temperature between 200 and 300 degrees Celsius, inclusive. By using a high-temperature etching process to increase the etching speed and the reactivity of the halogen gas, the side portions of the first variable resistance layer 106x and the second variable resistance layer 106y of the variable resistance element can be more easily etched at the same time as the patterning process. In this case, etching will not be performed beyond the first conductive film 105′ since the first conductive film 105′ comprises TaOₓ and a noble metal having a high etching selectivity ratio (platinum (Pt), iridium (Ir), palladium (Pd), etc.).

Next, as (c) in FIG. 5 shows, the first conductive film 105′ is patterned using a desired mask, such as the second electrode 107, and the patterned first conductive film 105′ is formed as the first electrode 105 connected to the contact plug 104.

It is preferable that this process is performed under the condition that the side portions of the variable resistance layer are resistive to etching. For example, the etching may be performed using a mixed gas including Ar and O₂. With the mixed gas of Ar and O₂, the side portions of the TaOₓ are, for the most part, not etched. As a result of these processes, a variable resistance element in which the variable resistance layer 106 is disposed between the first electrode 105 and the second electrode 107 is formed.

The nonvolatile memory element according to the fifth embodiment of the present invention can be realized by thereafter performing the usual processes of covering the variable resistance element with an interlayer insulating film, forming a contact plug connected to the second electrode of the variable resistance element, and forming an upper layer line connected to the contact plug, for example (not in Drawings).

Lastly, as (d) in FIG. 5 shows, a localized region F including a conductive filament whose degree of oxygen deficiency reversibly varies according to an application of a positive or negative electric pulse used for changing resistance is formed in the second variable resistance layer 106y by applying an initial breakdown voltage to the variable resistance layer 106 via the first electrode 105 and the second electrode 107.

With the above manufacturing method, the sides of the variable resistance layer 106 are removed via etching before the formation of the first electrode 105 in the manufacturing process of the variable resistance element including the second electrode 107, the variable resistance layer 106, and the first electrode 105 formed above the contact plug 104. As a result, the effective area of the variable resistance layer which contributes to the electrical properties can be reduced, and the initial breakdown voltage and application time thereof can be reduced.

Furthermore, since the surface area of the portion of the first metal oxide layer connected to the first electrode is formed to be larger than the surface area of the portion of the second metal oxide layer connected to the second electrode, and the second metal oxide layer has a higher oxygen content atomic percentage than the first metal oxide layer, compared to the nonvolatile memory element according to the first embodiment of the present invention, the nonvolatile memory element according to the fifth embodiment of the present invention formed with the above-described manufacturing method allows for a greater reduction in the degradation of electrical properties and variable resistance characteristics of the variable resistance element resulting from etching damage, since more of the etching damage portion, which progressed deeper in the upper portion of the variable resistance layer, is directly removed in the manufacturing of the nonvolatile memory element.

### Sixth Embodiment

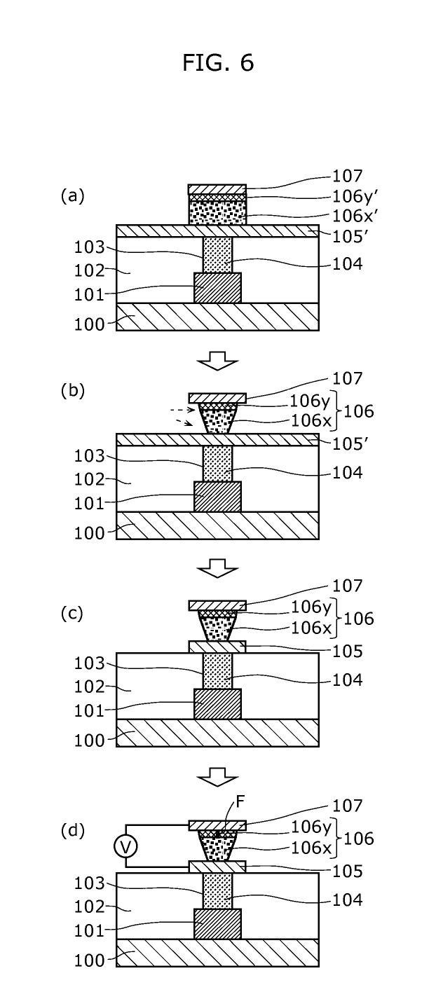

(a) through (c) in FIG. 6 are cross-sectional views showing the manufacturing method of a main component of the nonvolatile memory element according to the sixth embodiment of the present invention. The reference numerals for the constituents in (a) through (c) in FIG. 6 are the same as those in (a) through (i) in FIG. 1, and as such, explanations thereof will be omitted.

As (a) through (c) in FIG. 6 show, the difference between the manufacturing method of the nonvolatile memory element according to the first embodiment of the present invention and the manufacturing method of the nonvolatile memory element according to the sixth embodiment of the present invention is that in the latter, the surface area of the portion of the first metal oxide layer connected to the first electrode is formed to be smaller than the surface area of the portion of the second metal oxide layer connected to the second electrode, and the second metal oxide layer has a higher oxygen content atomic percentage than the first metal oxide layer. Consequently, since the processes before (a) in FIG. 6 are the same as those in (a) through (g) in FIG. 1, explanations thereof will be omitted.

First, as (b) in FIG. 6 shows, the first variable resistance layer 106x and the second variable resistance layer 106y are formed by etching the side portions of the first variable resistance layer and the second variable resistance layer at the same time as the formation of the variable resistance layer 106.

It is preferable that this process is performed under the condition that the side portions of the variable resistance layer 106 can easily be etched and that the variable resistance layer 106 can easily be formed in an inverted tapered shape. Etching may be performed in a mixed gas including a halogen gas, such as a mixed gas of Cl₂ and BCl₃, which is highly reactive with TaOₓ, and Ar as an additive, for example. By combining the effect of the anisotropic etching increased by the addition of Ar, and the effect of the isotropic etching from the halogen gas, the angle at which the plasma bombards the TaOₓ changes to an diagonal direction having an inward inclination toward the bottom.

Moreover, etching may be performed at a higher than conventional etching temperature, for example, at a temperature between 200 and 300 degrees Celsius, inclusive. By using a high-temperature etching process to increase the etching speed and the reactivity of the halogen gas, the side portions of the first variable resistance layer 106x and the second variable resistance layer 106y of the variable resistance element can be more easily etched at the same time as the patterning process. In this case, etching will not be performed beyond the first conductive film 105′ since the first conductive film 105′ is comprises TaOₓ and a noble metal having a high etching selectivity ratio (platinum (Pt), iridium (Ir), palladium (Pd), etc.).

Next, as (c) in FIG. 6 shows, the first conductive film 105′ is patterned using a desired mask, such as the second electrode 107, and the patterned first conductive film 105′ is formed as the first electrode 105 connected to the contact plug 104.

It is preferable that this process is performed under the condition that the side portions of the variable resistance layer are not etched. For example, the etching may be performed using a mixed gas including Ar and O₂. With the mixed gas of Ar and O₂, the side portions of the TaOₓ are, for the most part, not etched. As a result of these processes, a variable resistance element in which the variable resistance layer 106 is disposed between the first electrode 105 and the second electrode 107 is formed.

The nonvolatile memory element according to the sixth embodiment of the present invention can be realized by thereafter performing the usual processes of covering the variable resistance element with an interlayer insulating film, forming a contact plug connected to the second electrode of the variable resistance element, and forming an upper layer line connected to the contact plug, for example (not in Drawings).

Lastly, as (d) in FIG. 6 shows, a localized region F including a conductive filament whose degree of oxygen deficiency reversibly varies according to an application of an electric pulse is formed in the second variable resistance layer 106y by applying an initial breakdown voltage to the variable resistance layer 106 via the first electrode 105 and the second electrode 107.

With the above manufacturing method, the sides of the variable resistance layer 106 are removed via etching before the formation of the first electrode 105 in the manufacturing process of the variable resistance element including the second electrode 107, the variable resistance layer 106, and the first electrode 105 formed above the contact plug 104. As a result, the effective area of the variable resistance layer which contributes to the electrical properties can be reduced, and the initial breakdown voltage and application time thereof can be reduced.

Furthermore, since the surface area of the portion of the first metal oxide layer connected to the first electrode is formed to be smaller than the surface area of the portion of the second metal oxide layer connected to the second electrode, and the second metal oxide layer has a higher oxygen content atomic percentage than the first metal oxide layer, compared to the nonvolatile memory element according to the first embodiment of the present invention, the nonvolatile memory element according to the sixth embodiment of the present invention formed with the above-described manufacturing method allows for a greater a reduction in variable resistance characteristic inconsistency of each variable resistance element in the memory array since it is possible to narrow the region of the second metal oxide layer in which the localized region F, which includes the conductive filament reaching the first electrode, can be formed.

### Seventh Embodiment

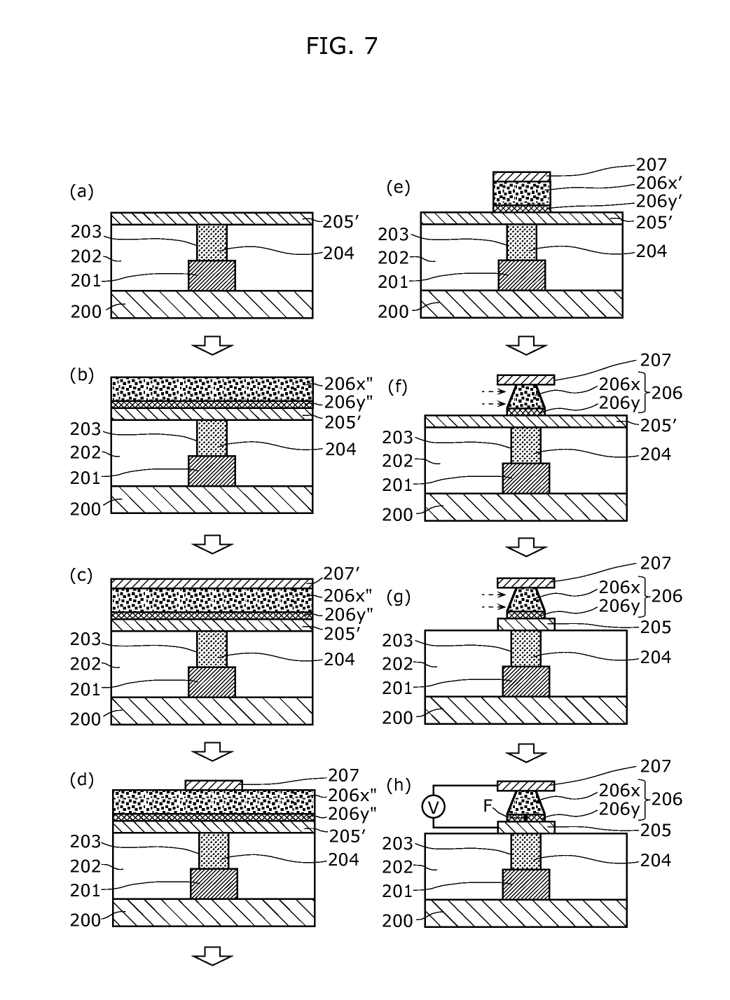

(a) through (g) in FIG. 7 are cross-sectional views showing the manufacturing method of a main component of the nonvolatile memory element according to the seventh embodiment of the present invention. The reference numerals for the constituents in (a) through (g) in FIG. 7 are the same as those in (a) through (i) in FIG. 1, and as such, explanations thereof will be omitted.

As (a) through (g) in FIG. 7 show, the difference between the manufacturing method of the nonvolatile memory element according to the first embodiment of the present invention and the manufacturing method of the nonvolatile memory element according to the seventh embodiment of the present invention is that in the latter, the stacked film that is patterned includes, in this order, the first conductive film comprising a noble metal (platinum (Pt), iridium (Ir), palladium (Pd), etc.), the first variable resistance film which is a high resistance film, the second variable resistance film which is a low resistance film, and the second conductive film comprising tantalum nitride, in contrast to patterning a stacked film including, in this order, the first conductive film comprising tantalum nitride, the first variable resistance film which is a low resistance film, the second variable resistance film which is a high resistance film, and the second conductive film comprising a noble metal. Consequently, since the processes before (b) in FIG. 7 are the same as those in (a) through (d) in FIG. 1, explanations thereof will be omitted.

Next, as (a) in FIG. 7 shows, a first conductive film 205′ (having a thickness between, for example, 50 nm and 200 nm, inclusive) comprising a noble metal (platinum (Pt), iridium (Ir), palladium (Pd), etc.) which will become a first electrode 205 is formed above the interlayer insulating layer to cover the contact plug by sputtering.

Next, as (b) in FIG. 7 shows, a variable resistance film including multiple layers each having different oxygen content atomic percentages, that is to say, a first variable resistance film 206y″ comprising a metal oxide and a second variable resistance film 206x″ comprising a metal oxide are formed in this order above the first conductive film 205′.

As conditions for achieving preferable variable resistance characteristics, the first variable resistance film 206y″ may have an oxygen content atomic percentage between 65 atm % and 75 atm %, inclusive, a resistivity of 10⁷ mΩ-cm and up, and a film thickness between 3 nm and 10 nm, inclusive. Likewise, the second variable resistance film 106x″ may have an oxygen content atomic percentage between 50 atm % and 65 atm %, inclusive, a resistivity of between 2 mΩ-cm and 50 mΩ-cm, inclusive, and a film thickness between 20 nm and 100 nm, inclusive.

Here, a method of sputtering a tantalum target in a mixed gas atmosphere of argon (Ar) and oxygen, in other words, a reactive sputtering method is used to form the first variable resistance film 206y″ and the second variable resistance film 206x″. It is to be noted that the first variable resistance film 206y″ is a film having a higher oxygen concentration and higher resistivity than the second variable resistance film 206x″.

Next, as (c) in FIG. 7 shows, a second conductive film 207′ containing tantalum nitride to become a second electrode 207 is formed above the second variable resistance film 206x″ after the patterning process.

Next, as (d) in FIG. 7 shows, the second conductive film 207′ is patterned using a desired mask, and the patterned second conductive film 207′ is formed as the second electrode 207. For example, the etching may be performed using a mixed gas including Cl₂ and Ar.

Next, as (e) in FIG. 7 shows, the second variable resistance film 206x″ and the first variable resistance film 206y″ are patterned using a desired mask. For example, a variable resistance film may be patterned using a hard mask comprising a material that is resistive to etching. The patterned variable resistance film forms the first variable resistance layer 206y′ and the second variable resistance layer 206x′. In this case, etching will not be performed beyond the first conductive film 205′ since the first conductive film 205′ comprises TaOₓ and a noble metal having a high etching selectivity ratio (platinum (Pt), iridium (Ir), palladium (Pd), etc.).

Next, as (f) in FIG. 7 shows, the first variable resistance layer 206y and the second variable resistance layer 206x are formed by etching the side portions of the first variable resistance layer 206y′ and the second variable resistance layer 206x′ of the patterned variable resistance element. A mixed gas including a halogen gas, which is highly reactive with TaOₓ, such as a mixed gas of Cl₂ and BCl₃, may be used for the etching process to remove the side portions and the patterning process, for example.

Moreover, etching may be performed at a higher than conventional etching temperature, for example, at a temperature between 200 and 300 degrees Celsius, inclusive. By using a high-temperature etching process to increase the etching speed and the reactivity of the halogen gas, the side portions of the first variable resistance layer 106x and the second variable resistance layer 106y of the variable resistance element can be more easily etched at the same time as the patterning process.

Furthermore, as (f) in FIG. 7 shows, the nonvolatile memory element according to the seventh embodiment of the present invention is formed such that the surface area of the portion of the first metal oxide layer connected to the first electrode is formed to be larger than the surface area of the portion of the second metal oxide layer connected to the second electrode, and the second metal oxide layer has a lower oxygen content atomic percentage than the first metal oxide layer. In this case, etching will not be performed beyond the first conductive film 205′ since the first conductive film 205′ comprises TaOₓ and a noble metal having a high etching selectivity ratio (platinum (Pt), iridium (Ir), palladium (Pd), etc.).

Next, as (g) in FIG. 7 shows, the first conductive film 205′ is patterned using a desired mask, such as the second electrode 207, and the patterned first conductive film 205′ is formed as the first electrode 205 connected to the contact plug 204.

It is preferable that this process is performed under the condition that the side portions of the variable resistance layer are not etched. For example, the etching may be performed using a mixed gas including Ar and O₂. With the mixed gas of Ar and O₂, the side portions of the TaOₓ are, for the most part, not etched. As a result of these processes, a variable resistance element in which the variable resistance layer 206 is disposed between the first electrode 205 and the second electrode 207 is formed. Afterwards, the hard mask may be removed.

The nonvolatile memory element according to the seventh embodiment of the present invention can be realized by thereafter performing the usual processes of covering the variable resistance element with an interlayer insulating film, forming a contact plug connected to the second electrode of the variable resistance element, and forming an upper layer line connected to the contact plug, for example (not in Drawings).

Lastly, as (h) in FIG. 7 shows, a localized region F including a conductive filament whose degree of oxygen deficiency reversibly varies according to an application of a positive or negative electric pulse used for changing resistance is formed in the first variable resistance layer 206y by applying an initial breakdown voltage to the variable resistance layer 206 via the first electrode 205 and the second electrode 207.

As described above, the nonvolatile memory element according to the seventh embodiment of the present invention is different from the nonvolatile memory element according to the first embodiment in that the structure thereof is reversed, vertically. As such, in the seventh embodiment, the first electrode 205, the first variable resistance layer 206y, the second variable resistance layer 206x, and the second electrode 207 correspond to the second electrode 107, the second variable resistance layer 206y, the first variable resistance layer 106x, and the first electrode 105 according to the first embodiment, respectively.

For this reason, the preferable materials, compositions, and combinations of the first electrode 205, the first variable resistance layer 206y, the second variable resistance layer 206x, and the second electrode 207 are the same as those described in detail in the first embodiment regarding the second electrode 107, the second variable resistance layer 206y, the first variable resistance layer 106x, and the first electrode 105.

With the above manufacturing method, the sides of the variable resistance layer 206 are removed via etching before the formation of the first electrode 205 in the manufacturing process of the variable resistance element including the second electrode 207, the variable resistance layer 206, and the first electrode 205 formed above the contact plug 204. As a result, the effective area of the variable resistance layer which contributes to the electrical properties can be reduced, and the initial breakdown voltage and application time thereof can be reduced.

Furthermore, the nonvolatile memory element according to the seventh embodiment of the present invention formed with the above-described manufacturing method is different from the nonvolatile memory element according to the first embodiment of the present invention in that it is formed such that the surface area of the portion of the first metal oxide layer connected to the first electrode comprising a noble metal is formed to be larger than the surface area of the portion of the second metal oxide layer connected to the second electrode, and the second metal oxide layer has a lower oxygen content atomic percentage than the first metal oxide layer. With this, a greater reduction in variable resistance characteristic inconsistency in each variable resistance element in the memory array as well as a greater reduction in the degradation of electrical properties and variable resistance characteristics of the variable resistance element can be achieved since more of the etching damage portion, which progressed deeper in the upper portion of the variable resistance layer, is directly removed and since it is possible to narrow the region of the second metal oxide layer in which the conductive path can be formed.

The above shows that the same advantageous effects of the variable resistance element according to the first embodiment can be achieved with the vertically reversed structure according to the seventh embodiment. Similarly, the same advantageous effects can be achieved with embodiments in which the structures of the variable resistance element according to the second through sixth embodiments are vertically reversed.

The manufacturing method of the nonvolatile memory element according to the present invention was described based on the first through seventh exemplary embodiments, but the scope of the present invention is not intended to be limited thereto. The present invention also includes variations of the embodiment conceived by those skilled in the art unless they depart from the spirit and scope of the present invention. Moreover, embodiments resulting from arbitrary combinations of constituent elements of different exemplary embodiments are intended to be included within the scope of the present invention as long as these do not depart from the essence of the present invention

### INDUSTRIAL APPLICABILITY

The present invention provides a manufacturing method of a variable resistance nonvolatile memory element by which a nonvolatile memory can be realized that is capable of stably producing, by removing the etching damage regions of the variable resistance layer and performing a stable and low-voltage initial breakdown, a localized region including a conductive filament having minimal inconsistencies in the variable resistance layer. Accordingly, the present invention is useful in a variety of electronic fields which use nonvolatile memory devices.

### REFERENCE SIGNS LIST

100, 200, 300 substrate
101, 201, 301 lower layer line
102, 202, 302 interlayer insulating layer
103, 203, 303 contact hole
104, 204, 304 contact plug
105, 205, 305 first electrode
105′, 205′, 305′ first conductive film
106, 206 variable resistance layer (after side-portion etching)
106x, 206y first variable resistance layer (after side-portion etching)
106x′, 206y′ first variable resistance layer (before side-portion etching)
106x″, 206y″, 306x″ first variable resistance film
106y, 206x second variable resistance layer (after side-portion etching)
106y′, 206x′ second variable resistance layer (before side-portion etching)
106y″, 206x″, 306y″ second variable resistance film
107, 207, 307 second electrode
107′, 207′ second conductive film
306 variable resistance layer (after side-portion oxidation)
306x first variable resistance layer (after side-portion oxidation)
306x′ first variable resistance layer (before side-portion oxidation)
306y second variable resistance layer (after side-portion oxidation)
306y′ second variable resistance layer (before side-portion oxidation)
306z insulating region
308 etching damage region (after side-portion oxidation)
308′ etching damage region (before side-portion oxidation)

1. A method of manufacturing a nonvolatile memory element, the method comprising:
forming a first electrode layer above a substrate;
forming a metal oxide layer on the first electrode layer, the metal oxide layer including at least a first metal oxide layer and a second metal oxide layer having different degrees of oxygen deficiency;
forming a second electrode layer on the metal oxide layer;
forming a second electrode by patterning the second electrode layer;
forming a variable resistance layer by patterning the first metal oxide layer and the second metal oxide layer, the variable resistance layer including at least a first variable resistance layer and a second variable resistance layer having different degrees of oxygen deficiency;
removing a side portion of the variable resistance layer in a surface parallel to a main surface of the substrate to a position that is further inward than an edge of the second electrode; and
forming a first electrode by patterning the first electrode layer after or during the removing.

2. The method of manufacturing a nonvolatile memory element according to claim 1,
wherein in the forming of a first electrode, the first electrode is formed to have a profile larger than a profile of the variable resistance layer when observed from a direction perpendicular to the main surface of the substrate.

3. The method of manufacturing a nonvolatile memory element according to claim 1,
wherein the forming of a variable resistance layer and the removing are performed in a single etching process at once.

4. The method of manufacturing a nonvolatile memory element according to claim 1,
wherein the forming of a first electrode and the removing are performed in a single etching process at once.

5. The method of manufacturing a nonvolatile memory element according to claim 1,
wherein in the removing, the side portion of the variable resistance layer is removed by wet etching.

6. The method of manufacturing a nonvolatile memory element according to claim 1,
wherein the forming of a metal oxide layer includes forming the first metal oxide layer on the first electrode layer and forming the second metal oxide layer on the first metal oxide layer, and
in the removing, the first variable resistance layer is formed to have a cross-sectional surface area in a plane parallel to the main surface of the substrate that is larger than a cross-sectional surface area of the second variable resistance layer in a plane parallel to the main surface of the substrate.

7. The method of manufacturing a nonvolatile memory element according to claim 1,
wherein the forming of a metal oxide layer includes forming the first metal oxide layer on the first electrode layer and forming the second metal oxide layer on the first metal oxide layer, and
in the removing, the first variable resistance layer is formed to have a cross-sectional surface area in a plane parallel to the main surface of the substrate that is smaller than a cross-sectional surface area of the second variable resistance layer in a plane parallel to the main surface of the substrate.

8. The method of manufacturing a nonvolatile memory element according to claim 1,
wherein in the forming of a metal oxide layer, each of the first metal oxide layer and the second metal oxide layer comprises a transition metal oxide or aluminum oxide.

9. The method of manufacturing a nonvolatile memory element according to claim 8,
wherein in the forming of a metal oxide layer, the transition metal oxide is tantalum oxide, hafnium oxide, or zirconium oxide.

10. The method of manufacturing a nonvolatile memory element according to claim 9,
wherein the first metal oxide layer and the second metal oxide layer comprise a same constituent metal.

11. The method of manufacturing a nonvolatile memory element according to claim 9,
wherein the first metal oxide layer and the second metal oxide layer comprise different constituent metals.

12. The method of manufacturing a nonvolatile memory element according to claim 1, further comprising
forming, in the variable resistance layer, by application of a first electric pulse to the variable resistance layer, a region having a resistance value that changes reversibly in response to an application of (i) a second electric pulse having a first polarity and having an amplitude that is smaller than an amplitude of the first electric pulse, or (ii) a third electric pulse having a second polarity that is different from the first polarity and having an amplitude that is smaller than the amplitude of the first electric pulse.

13. The method of manufacturing a nonvolatile memory element according to claim 12,
wherein the region having the resistance value that changes reversibly is a localized region that includes a conductive filament and is formed in a less oxygen deficient one of the first variable resistance layer and the second variable resistance layer, and
the localized region has a degree of oxygen deficiency that changes reversibly in response to the second electric pulse or the third electric pulse.

14. (canceled)
